(19) United States
(12) Patent Application Publication
(10) Pub. No.: US 2003/0218253 A1
(43) Pub. Date: Nov. 27, 2003

(54) Process for formation of a wiring network using a porous interlevel dielectric and related structures

(76) Inventors: Steven C. Avanzino, Cupertino, CA (US); Darrell M. Erb, Los Altos, CA (US); Fei Wang, San Jose, CA (US); Sergey Lopatin, Santa Clara, CA (US)

Correspondence Address: David A. Blumenthal, FOLEY & LARDNER, 35th Floor, 2029 Century Park East, Los Angeles, CA, 90067-3021, US

(21) Appl. No.: 10/017,886

(22) Filed: Dec. 13, 2001

(51) Int. Cl. H01L 21/4763; H01L 23/58; H01L 29/40; H01L 23/48

(52) U.S. Cl. 257/758; 438/622; 438/623; 438/638; 438/643; 438/687; 257/759; 257/762

(57) ABSTRACT

A precursor of a low-k porous dielectric is applied to an integrated circuit substrate. The precursor comprises a host thermosetting material and a porogen. Crosslinking of at least some of the first host thermosetting material is produced to form a low-k dielectric matrix without decomposing all of the porogen. This leaves a solid nonporous layer of the low-k dielectric matrix. Wiring elements are then inlaid in the low-k dielectric matrix. After the wiring elements are formed, remaining porogen is decomposed to leave pores in the low-k dielectric matrix. The resulting wiring elements are smooth walled.

### FIELD OF THE INVENTION

Embodiments of the present invention pertain to semiconductor fabrication, and in particular to porous interlevel dielectric layers.

### BACKGROUND TECHNOLOGY

Integrated circuits (ICs) are manufactured by forming discrete semiconductor devices such as MOSFETS and bipolar junction transistors on a semiconductor substrate, and then forming a metal wiring network that connects the devices to create circuits. The wiring network is composed of individual metal wirings called interconnects that are connected to the devices by vertical contacts and are connected to other interconnects by vertical vias. A typical wiring network employs multiple levels of interconnects and vias.

The performance of integrated circuits is determined in large part by the conductivity and capacitance of the wiring network. Copper has been adopted as the preferred metal for wiring networks because of its low resistivity compared to other metals. To address capacitance issues, low dielectric constant (“low-k”) materials have been developed for use as interlevel dielectrics for surrounding the wiring elements of the network in place of the conventional silicon oxide interlevel dielectric. Conventional low-k materials are typically spin-on organic compounds with a dielectric constant of less than about 3.5, compared to a dielectric constant of about 7.0 for silicon oxides.

To further improve over the conventional spin-on low-k organics, recent efforts have focused on the development of porous dielectric materials that achieve a reduced overall dielectric constant by virtue of pores formed within the material. Many of these materials are formed by a spin-on method using a solution of a precursor, followed by thermal processing to convert the precursor into a porous dielectric.

One type of porous low-k dielectric is formed from a precursor compound comprised of a thermosetting host material and a thermally degradable “porogen” material. In conventional applications, a solution of the precursor is applied to a substrate by spin-on processing. Thermal processing is then performed to convert the precursor to a porous low-k dielectric. The thermal processing causes crosslinking of the host material to form a low-k dielectric matrix. The thermal processing concurrently causes phase separation of the porogen from the host material. The phase separated porogen collects in nanoscopic domains within the host material and thermally decomposes into volatile decomposition products that diffuse out of the low-k dielectric and leave pores in their place. Dow Chemical's porous SILK product and JSR Corporation's JSR 5109 product are examples of commercially available precursors that utilize an organic host material. IBM's DendriGlass product is an example of a commercially available precursor that utilizes a silicon-containing host material comprising a blend of organosilicates. Further information—regarding the compositions and properties of various porous dielectric materials and their precursors is provided in Designing Porous Low-k Dielectrics, Semiconductor International, May 2001, and “Industry Divides on Low-k Dielectric Choices,” Semiconductor International, May 2001, each of which is incorporated herein by reference.

While porous interlevel dielectrics offer the potential for significant reduction of capacitance effects in wiring networks, the integration of porous materials with conventional processing techniques entails a number of problems. For example, conventional copper via and interconnect structures are formed by damascene or dual damascene processes in which the copper is deposited in trenches formed in a previously deposited interlevel dielectric material. In the case of conventional nonporous dielectrics, these trenches have generally smooth surfaces. However, the use of the same techniques with porous materials produces rough trench surfaces having open pores. The open pores make it difficult to achieve continuous coverage by barrier materials, which leads to diffusion of copper into the surrounding dielectric and resultant shorting problems. Similar coverage problems occur with seed layer materials, resulting in discontinuities in deposition of bulk conductive material and increased resistance. Rough sidewalls also produce scattering of electrons that further increases resistance.

Consequently, there is a need for improved techniques for integrating porous interlevel dielectrics with copper wiring networks so that the aforementioned disadvantages of rough sidewalls are avoided.

### SUMMARY OF THE DISCLOSURE

In accordance with embodiments of the present invention, a solution of a precursor comprising a host thermosetting material and a porogen is applied to an integrated circuit substrate. Crosslinking is produced in the host material to form a low-k dielectric matrix without decomposing all of the porogen. This produces a relatively solid nonporous later of low-k dielectric. Wiring elements are then inlaid in the low-k dielectric matrix. After the wiring elements are formed, the remaining porogen is decomposed and diffuses out of the low-k matrix, leaving porous low-k dielectric material. The wiring elements formed in this manner are smooth walled and thus are integrated with interlevel porous dielectric in a manner that avoids the aforementioned disadvantages.

Embodiments of the invention may pertain to a method for forming a wiring network of an integrated circuit using a single inlay process. In one such embodiment, a substrate comprising a first conductive element is provided. A precursor comprising a host thermosetting material and a porogen is applied to the substrate. Crosslinking of at least some of the host material is then produced without decomposing all of the porogen, yielding a low-k dielectric matrix. A second conductive element is then inlaid in the precursor in contact with the first conductive element. Remaining porogen is then decomposed to produce a porous dielectric material.

Related embodiments of the invention may pertain to a wiring network for an integrated circuit that integrates an inlaid wiring element with porous interlevel dielectric. In one such embodiment, a second conductive element is formed in contact with a first conductive element. Advantageously, the walls of the second conductive element are smooth while also being surrounded by porous interlevel dielectric.

Further embodiments of the invention may pertain to methods for forming a wiring network of an integrated circuit using a dual inlay process. In one such embodiment, an integrated circuit substrate comprising a first conductive element is provided. A first precursor comprising a first host thermosetting material and a first porogen is then applied to the substrate. Crosslinking is produced in the first host material to form a low-k dielectric matrix without decomposing all of the first porogen. This produces a relatively solid nonporous later of low-k dielectric. A first stop layer is then formed over the low-k dielectric. A second precursor comprising a second host thermosetting material and a second porogen is then applied to the first stop layer. Crosslinking is produced in the second host material to form a low-k dielectric matrix without decomposing all of the second porogen. This produces a second relatively solid nonporous later of low-k dielectric. A second stop layer is then formed over the second low-k dielectric. A trench defining a dual damascene structure is formed in the first and second stop layers and first and second low-k matrixes, and a second conductive element is inlaid in the trench in contact with the first conductive element. The remaining first and second porogen is then decomposed to form first and second layers of porous interlevel dielectric.

Related embodiments of the invention may pertain to a wiring network for an integrated circuit that integrates a dual damascene wiring element with porous interlevel dielectric. In one such embodiment, a dual damascene conductive element is formed in contact with a first conductive element and, advantageously, the walls of the dual damascene conductive element are smooth while also being surrounded by porous interlevel dielectric.

Other features and advantages of the present invention, as well as alternatives to the preferred embodiments disclosed herein, will become apparent to those skilled in the art from the following drawings and detailed description and from the appended claims.

### DESCRIPTION OF THE DRAWINGS

Preferred embodiments will hereafter be described with reference to the accompanying drawings, wherein like numerals denote like elements, and in which:

FIG. 1 shows a substrate comprising a first conductive element;

FIG. 2 shows the structure of FIG. 1 after application of a solution of a precursor;

FIG. 3 shows the structure of FIG. 2 during processing to produce crosslinking in a host material of the first precursor to form a low-k dielectric matrix;

FIG. 4 shows the structure of FIG. 3 after formation of a stop layer on the low-k dielectric matrix;

FIG. 5 shows the structure of FIG. 4 after formation of a trench;

FIG. 6 shows the structure of FIG. 5 after formation of a second conductive element in the trench;

FIG. 7 shows the structure of FIG. 6 after decomposition of porogen to form porous dielectric;

FIG. 8 shows a method in accordance with a first preferred embodiment of the invention;

FIG. 9 shows the structure of FIG. 4 after application of a solution of a second precursor;

FIG. 10 shows the structure of FIG. 8 during processing to produce crosslinking in a host material of the second precursor to form a second low-k dielectric matrix;

FIG. 11 shows the structure of FIG. 10 after formation of a second stop layer on the second low-k dielectric matrix;

FIG. 12 shows the structure of FIG. 11 after etching to form a trench;

FIG. 13 shows the structure of FIG. 12 after further etching to define a dual damascene trench;

FIG. 14 shows the structure of FIG. 13 after inlaying a conductive element in the trench;

FIG. 15 shows the structure of FIG. 14 after decomposition of first and second porogens to form first and second porous dielectrics; and

FIG. 16 shows a method in accordance with a second preferred embodiment of the invention.

### DETAILED DESCRIPTION OF PREFERRED EMBODIMENTS

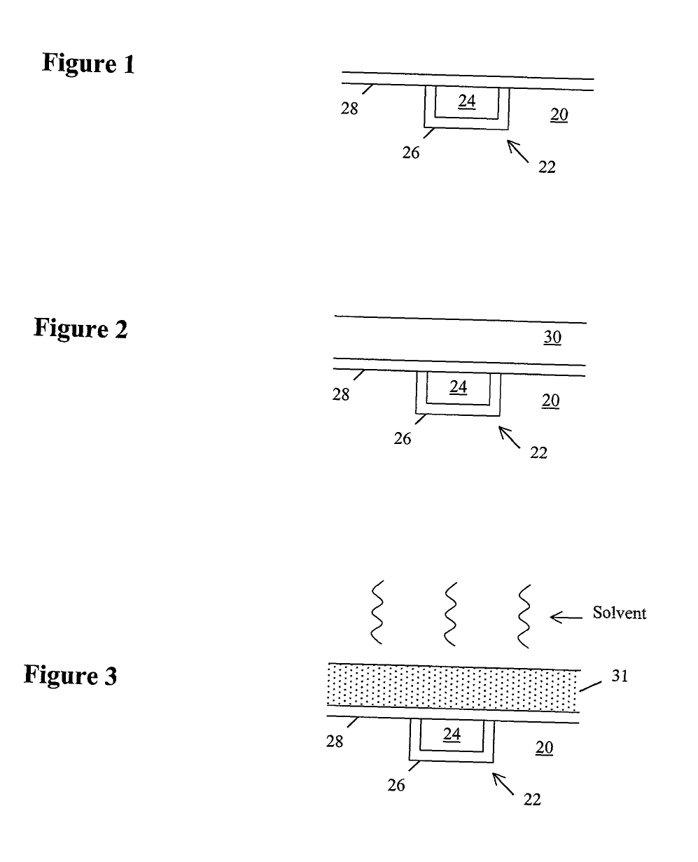

FIGS. 1 through 7 show structures formed at successive stages of a process for forming a conductive element such as a via or interconnect in accordance with a first preferred embodiment of the invention.

FIG. 1 shows a structure comprising a substrate 20 having formed therein a first conductive element 22 comprising a bulk copper conductor 24 surrounded by a barrier layer 26. The first conductive element may be a via or an interconnect. The barrier layer 26 may be formed of any barrier material such as Ta, TaN, CVD TiNSi, or a copper incorporating an alloying element such as Mg. A passivation layer 28 forms the surface of the substrate. The passivation layer may be comprised of any passivation material such as SiN, SiON, or silicon carbide.

FIG. 2 shows the structure of FIG. 1 after application of a solution of a precursor 30 of a porous dielectric to the substrate. The solution is typically applied by a spin-on process. The precursor 30 comprises a host thermosetting material and a porogen. The precursor may comprise any of the aforementioned precursors or other similar materials.

FIG. 3 shows the structure of FIG. 2 during thermal processing to produce crosslinking in the host material without decomposing all of the porogen in the precursor. This yields a low-k dielectric matrix 31 that contains porogen. This thermal processing typically eliminates solvent from the precursor solution. Some shrinkage of the layer may occur at this time. In one exemplary embodiment, Dow Porous Silk precursor is subjected to thermal processing at temperature in the range of approximately 200 degrees C. to less than approximately 390 degrees C. This temperature range has been found to produce sufficient crosslinking of the host material to support etching and filling of the host material as described below, while also leaving enough porogen to produce sufficient porosity in later processing.

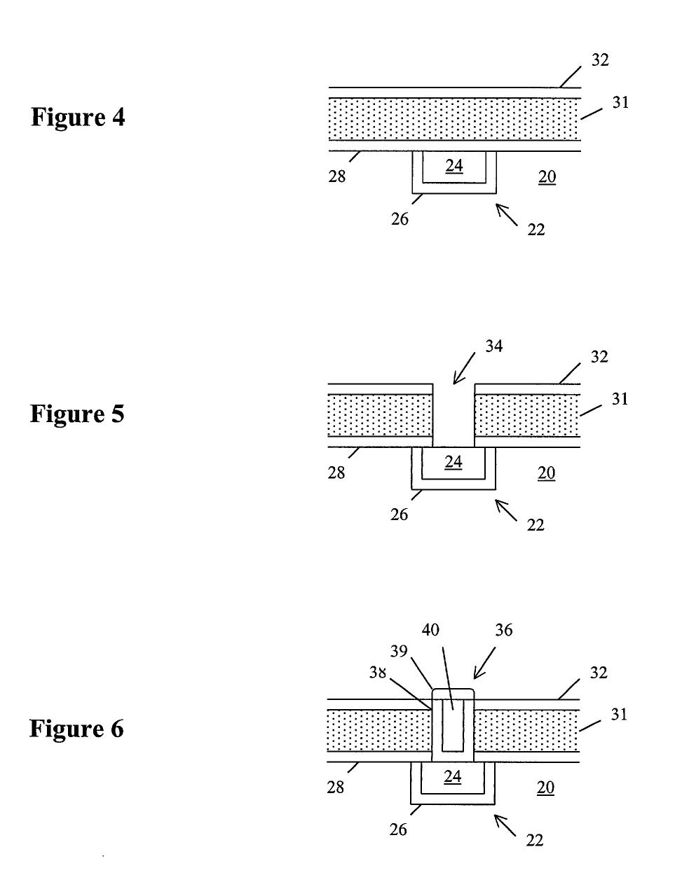

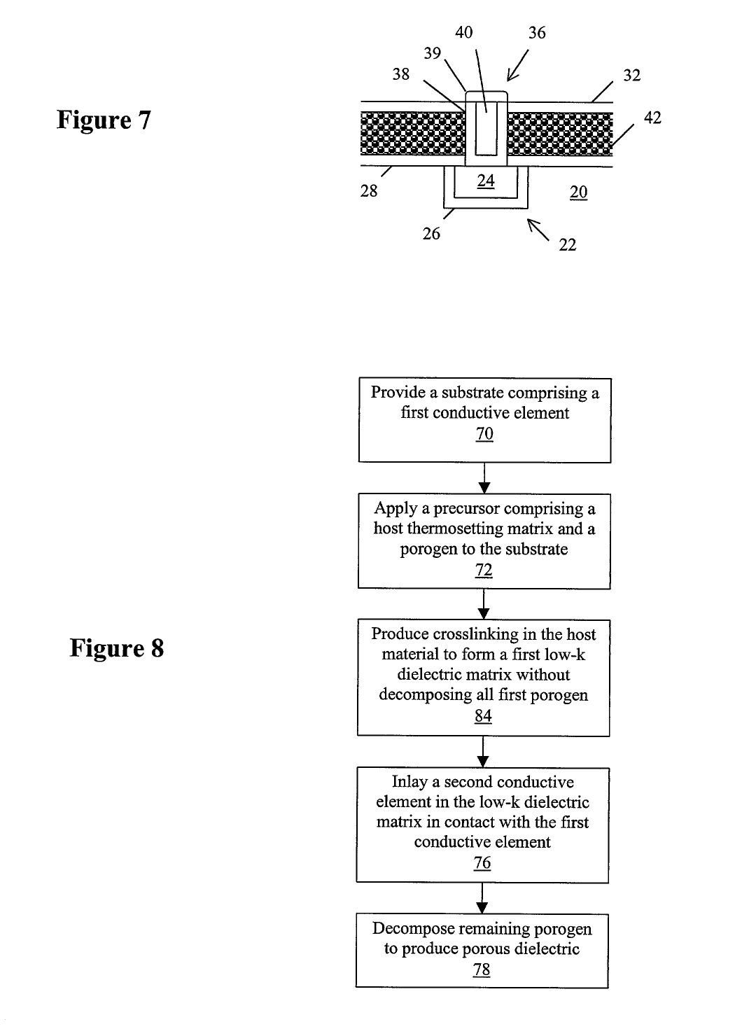

FIG. 4 shows the structure of FIG. 3 after formation of a stop layer 32 over the low-k dielectric matrix 31. In some cases the stop layer 32 may comprise any stop layer material such as SiN, SiC or SiON, however in other cases the choice of the stop layer material may depend upon the type of precursor used, as discussed further below in regard to FIG. 7.

FIG. 5 shows the structure of FIG. 4 after formation of a trench 34 in the stop layer 32, the low-k dielectric matrix 31, and the passivation layer 28 to expose the bulk copper conductor 24 of the first conductive element 22 in the substrate 20. The trench may be formed, for example, by a two stage etching process using a fluorine plasma etch to etch the stop layer 32, followed by an oxygen, nitrogen or hydrogen plasma etch to etch the low-k dielectric matrix 31 using the stop layer 32 as a hard mask. The structure of the trench may define the shape of an interconnect or a via. Because the low-k dielectric matrix is nonporous at this stage of processing, the trench surfaces are essentially smooth since there are no open pores in the side walls.

FIG. 6 shows the structure of FIG. 5 after a second conductive element 36 is inlaid in the trench in contact with the bulk copper conductor 24 of the first conductive element 22. The second conductive element 36 comprises a barrier layer 38 and a bulk copper conductor 40. The barrier layer 38 may comprise any barrier material such as Ta, TaN, CVD TiNSi, or a copper incorporating an alloying element such as Mg. The bulk copper conductor 40 may be deposited by physical vapor deposition, or by physical vapor deposition of a seed layer followed by electroplating or electroless plating of bulk copper. The bulk copper may include one or more alloying elements such as Sn, In, Zr, Ca, Al, Zn, Cr, La or Hf. Additional processing such as seed layer enhancement or alloying may also be performed. Deposition of the barrier and bulk materials is followed by planarization such as by CMP to remove the overburden of bulk copper. The bulk copper is then annealed, preferably at a temperature greater than 250 degrees C. and not greater than 390 degrees C., and a cap material 39 such as tungsten is then selectively deposited on the second conductive element 36, yielding the structure shown in FIG. 6. Because the low-k dielectric matrix 31 is nonporous at this stage of processing, the barrier layer deposited in the trench forms a smooth walled, continuous layer within the trench, and bulk copper conductor formed on the barrier layer is likewise continuous.

FIG. 7 shows the structure of FIG. 6 after decomposition of any porogen that remains in the low-k dielectric matrix 31, such as by thermal processing, to produce a porous dielectric layer 42 between the passivation layer 28 and the stop layer 32. For the Dow Porous Silk material, processing is preferably performed at a temperature greater than 390 degrees C. The stop layer is chosen to be permeable to the decomposition products and thus to allow out diffusion of the decomposition products. Typical porogen decomposition products are CO₂ and H₂O. Where the Dow Porous Silk product is used, the Dow's “Etch Stop” (trade name) material provides sufficient permeability to decomposition products.

Because the porosity of the porous dielectric material 42 is created after the structure of the second conductive element 36 has been inlaid in the nonporous precursor 30, the subsequent presence of open pores at the surfaces of the second conductive element does not degrade the structure or electrical characteristics of the second conductive element.

In a first alternative to the processing of the first preferred embodiment shown in FIGS. 6-7, the stop layer 32 of FIG. 6 may be removed by selective etching prior to decomposition of remaining porogen. The copper elements may then be treated to remove corrosion, such as by polishing or plasma treatment, and the entire structure may then be covered with a cap layer. In this alternative, the diffusion of any decomposition products proceeds more quickly because of the absence of an overlying layer.

In a second alternative to the processing of the first preferred embodiment shown in FIGS. 6-7, the selectively deposited cap 39 may be replaced with a sacrificial cap layer that covers the entire surface of the second conductive element 36 and the surrounding stop layer 32. The sacrificial cap layer may be formed before decomposition of porogen, and may be removed by polishing after decomposition. The entire structure may then be covered by a diffusion barrier. The sacrificial cap layer material must be chosen to be permeable to the porogen decomposition products.

After formation of the structure illustrated in FIG. 7, or the structures formed in accordance with any of the three aforementioned alternatives, further processing may be performed, such as forming additional levels of wiring and interlevel dielectric.

FIG. 8 illustrates a basic process for forming a wiring network of an integrated circuit encompassing the first preferred embodiment and the aforementioned alternatives, as well as further alternatives that will be apparent to those skilled in the art. Initially, an integrated circuit substrate is provided (70). The substrate comprises a first conductive element. A solution of a precursor of a porous dielectric is then applied to the substrate (72). The precursor comprises a host thermosetting matrix and a porogen. Crosslinking of at least some of the host material is then produced to form a low-k dielectric matrix (74). The crosslinking is produced without decomposing all of the porogen. A second conductive element is then inlaid in the low-k dielectric matrix in contact with the first conductive element (76). Remaining porogen is then decomposed to leave pores in the low-k dielectric matrix (78).

Thus, in accordance with the processing of FIG. 8, a wiring network for an integrated circuit may be formed that integrates inlaid wiring elements with porous interlevel dielectric as illustrated in FIG. 7, or as would be formed in accordance with any of the aforementioned alternatives or other alternatives. Such a wiring network includes the first and second conductive elements, and, advantageously, the walls of the second conductive element are smooth while also being surrounded by porous interlevel dielectric and formed by an inlay process.

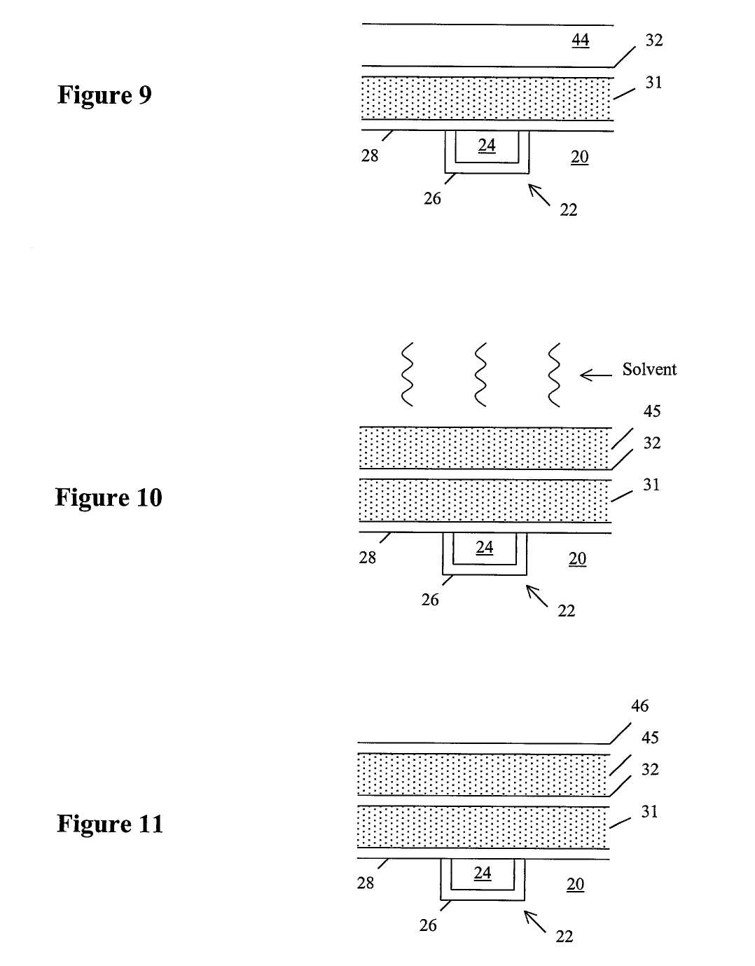

FIGS. 9-15 show alternative processing that may be performed in place of the processing shown in FIGS. 5-7 and the aforementioned alternatives thereto in accordance with a second preferred embodiment to form a dual damascene structure. In the second preferred embodiment, the first conductive element 22 typically comprises an interconnect, in contact with which a dual damascene structure is to be formed.

FIG. 9 shows the structure of FIG. 4 after application to the stop layer 32 of a second precursor 44. The second precursor 44 is preferably the same precursor as the first precursor 30, but it need not be the same.

FIG. 10 shows the structure of FIG. 9 during thermal processing to produce crosslinking in the host thermosetting material of the second precursor to form a second low-k dielectric matrix 45. The resulting structure thus has a first layer 31 of low-k dielectric matrix and a second layer 45 of low-k dielectric matrix.

FIG. 11 shows the structure of FIG. 10 after formation of a second stop layer 46 over the second low-k dielectric matrix 45. Thus FIG. 11 is seen to have a first stop layer 32 and a second stop layer 46. As discussed above, in some cases the second stop layer 46 may comprise any stop layer material such as SiN, SiC or SiON, however the choice of stop layer material may depend upon the type of precursor used, as discussed above.

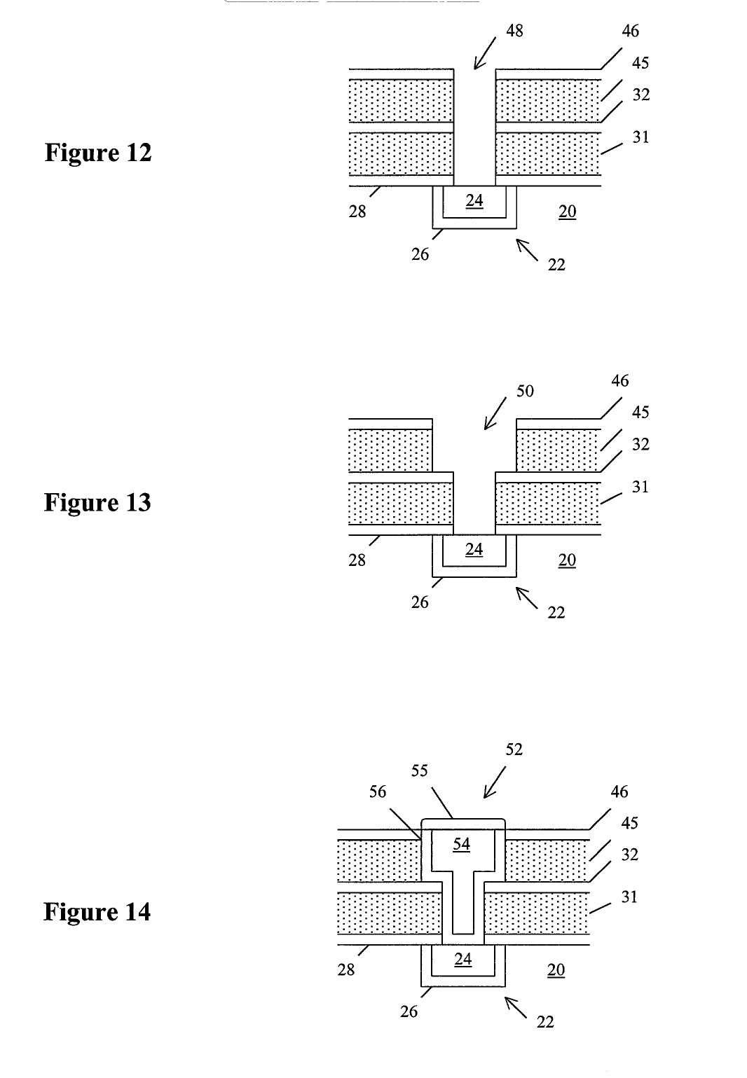

FIG. 12 shows the structure of FIG. 11 after formation of a trench 48 in the second stop layer 46, second low-k dielectric matrix 45, first stop layer 32, first low-k dielectric matrix 31, and passivation layer 28 to expose the bulk copper conductor 24 of the first conductive element 22 in the substrate 20. The trench may be formed, for example, by a multiple stage etching process using the stop layer 46 as a hard mask as described above. The structure of the trench 48 defines the shape of a via portion of a dual damascene conductive element. Because the low-k dielectric matrixes 31, 45 are nonporous at this stage of processing, the trench surfaces are essentially smooth since there are no open pores in the side walls.

FIG. 13 shows the structure of FIG. 12 after further etching to widen the trench in the stop layer 46 and the second low-k dielectric matrix 45, thus yielding a trench 50 defining the shape of the interconnect and via portions of a dual damascene conductive element. The trench may be widened using a multiple stage etch process employing the stop layer 46 as a hard mask as described above. Because the precursors 30, 44 remain nonporous at this stage of processing, the trench surfaces are essentially smooth since there are no open pores in the side walls.

FIG. 14 shows the structure of FIG. 13 after a second conductive element 52 is inlaid in the trench in contact with the bulk copper conductor 24 of the first conductive element 22. The second conductive element comprises a barrier layer 56 and a bulk copper conductor 54. The barrier layer 56 may comprise any barrier material such as Ta, TaN, CVD TiNSi, or a copper alloy incorporating Mg. The bulk copper conductor 54 may be deposited by physical vapor deposition, or by physical vapor deposition of a seed layer followed by electroplating or electroless plating of bulk copper. The bulk copper may include one or more alloying elements such as Sn, In, Zr, Ca, Al, Zn, Cr, La or Hf. Additional processing such as seed layer enhancement or alloying may also be performed. Deposition of the barrier and bulk materials is followed by planarization such as by CMP to remove the overburden of bulk copper. The bulk copper is then annealed, and a cap material 55 such as tungsten is then selectively deposited on the second conductive element 52, yielding the structure shown in FIG. 14. Because the low-k dielectric matrixes 31, 45 are nonporous at this stage of processing, the barrier layer 56 deposited in the trench forms a smooth walled, continuous layer within the trench, and bulk copper conductor 54 formed on the barrier layer 56 is likewise continuous, that is, not discontinuous in the manner that would result from inlaying in a trench having porous sidewalls.

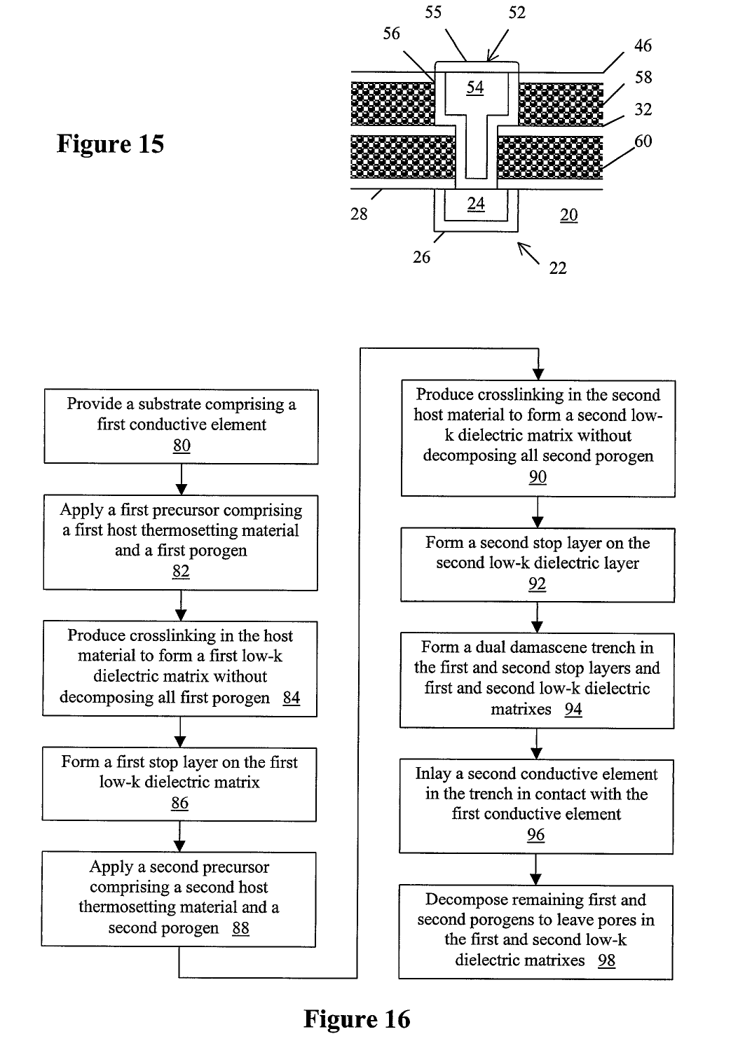

FIG. 15 shows the structure of FIG. 14 after decomposition of porogen remaining in the low-k dielectric matrixes 31, 45. This produces a first porous dielectric layer 60 between the passivation layer 28 and the first stop layer 32, and a second porous dielectric layer 58 between the stop layer 32 and the second stop layer 46. The first and second stop layers 32 and 46 are respectively chosen to be permeable to the decomposition products of the porogens and thus to allow out diffusion of the decomposition products within a reasonable period of time. Because any decomposition products from the first porogen must diffuse through the first stop layer 32, the second low-k dielectric matrix 58 and the second stop layer 46, the amount of time required to complete the porogen decomposition stage of processing will be greater than in the first preferred embodiment. However, depending on the overall integration scheme, the second preferred embodiment may save time and enhance throughput and yield compared to the formation of a comparable structure by twice performing single inlay processing in the manner of FIGS. 1-7.

Because the porosity of the porous dielectrics 58, 60 is created after the structure of the second conductive element 52 has been defined through dual damascene processing using the nonporous low-k matrixes 31, 45, the subsequent presence of open pores at the surfaces of the second conductive element does not degrade the structure or electrical characteristics of the second conductive element.

In a first alternative to the processing of the second preferred embodiment shown in FIGS. 14-15, the stop layer 46 of FIG. 15 may be removed by selective etching prior to decomposition of remaining porogen. The copper elements may be then be treated to remove corrosion, such as by polishing or plasma treatment, and the entire structure may then be covered with a cap layer. In this alternative, the diffusion of any decomposition products proceeds more quickly because of the absence of an overlying stop layer.

In a second alternative to the processing of the second preferred embodiment shown in FIGS. 14-15, the selectively deposited cap 55 may be replaced with a sacrificial cap layer of a dielectric material that covers the entire surface of the second conductive element 52 and the surrounding second stop layer 46. The sacrificial cap layer may be formed before decomposition of porogen, and may be removed by polishing after decomposition. The entire structure may then be covered by a diffusion barrier. The sacrificial cap material must be chosen to be permeable to the porogen decomposition products.

After formation of the structure illustrated in FIG. 15, or the structures formed in accordance with any of the aforementioned alternatives, further processing may be performed, such as forming additional levels of wiring and interlevel dielectric.

FIG. 16 illustrates a basic process for forming a wiring network of an integrated circuit encompassing the second preferred embodiment and the four aforementioned alternatives, as well as further alternatives that will be apparent to those skilled in the art. Initially, an integrated circuit substrate is provided (80). The substrate comprises a first conductive element. A first precursor is then applied to the substrate (82). The precursor comprises a first host thermosetting material and a first porogen. Crosslinking of at least some of the first host material is then produced without decomposing all of the first porogen to form a first low-k dielectric matrix (84). A first stop layer is then formed on the first low-k dielectric matrix (86).

A second precursor is then applied to the first stop layer (88). Crosslinking of at least some of the second host material is then produced without decomposing all of the second porogen to form a second low-k dielectric matrix (90). A second stop layer is then formed on the second precursor (92). A trench defining a dual damascene structure is then formed in the first and second stop layers and first and second low-k dielectric matrixes (94), and a second conductive element is inlaid in the trench in contact with the first conductive element (96). Remaining porogen in the first and second low-k dielectric matrixes is then decomposed to leave pores in the first and second low-k dielectric matrixes (98).

Thus, in accordance with the processing of FIG. 16, a wiring network for an integrated circuit may be formed that integrates inlaid dual damascene conductive elements with porous interlevel dielectric as illustrated in FIG. 16, or as would be formed in accordance with any of the aforementioned alternatives or other alternatives. Such a wiring network includes the first conductive element and a dual damascene second conductive element, and, advantageously, the walls of the dual damascene second conductive element are smooth while also being surrounded by porous interlevel dielectric and formed by an inlay process.

It will be apparent to those having ordinary skill in the art that the tasks described in the above processes are not necessarily exclusive of other tasks, but rather that further tasks may be incorporated into the above processes in accordance with the particular structures to be formed. For example, intermediate processing tasks such as seed layer formation, seed layer enhancement, alloying such as by implantation or diffusion, annealing, cleaning, formation and stripping of oxidation layers, formation and removal of passivation layers or protective layers between processing tasks, formation and removal of photoresist masks and other masking layers, as well as other tasks, may be performed along with the tasks specifically described above. Further, the process need not be performed on an entire substrate such as an entire wafer, but rather may be performed selectively on sections of the substrate. Thus, while the embodiments illustrated in the figures and described above are presently preferred, it should be understood that these embodiments are offered by way of example only. The invention is not limited to a particular embodiment, but extends to various modifications, combinations, and permutations that fall within the scope and spirit of the appended claims.

What is claimed is:

1. A method for forming a wiring network of an integrated circuit, comprising:
providing an integrated circuit substrate comprising a first conductive element;
applying a precursor to the substrate, the precursor comprising a host thermosetting material and a porogen;
producing crosslinking of at least some of the host thermosetting material to form a low-k dielectric matrix without decomposing all of the porogen;
inlaying a second conductive element in the low-k dielectric matrix in contact with the first conductive element; and
decomposing remaining porogen to leave pores in the low-k dielectric matrix.

2. The method claimed in claim 1, wherein the substrate further comprises a passivation layer overlying at least the first conductive element.

3. The method claimed in claim 1, wherein the first conductive element comprises a via and the second conductive element comprises an interconnect.

4. The method claimed in claim 1, wherein the first conductive element comprises an interconnect and the second conductive element comprises a via.

5. The method claimed in claim 1, wherein said inlaying is preceded by forming a stop layer on the low-k dielectric matrix, the stop layer being permeable to decomposition products of the porogen.

6. The method claimed in claim 1, wherein said inlaying is preceded by forming a stop layer on the low-k dielectric matrix, and
wherein said decomposing is preceded by removing the stop layer.

7. The method claimed in claim 1, wherein inlaying the second conductive element is followed by selectively depositing a metal cap on the second conductive element.

8. The method claimed in claim 1, wherein inlaying the second conductive element is followed by forming a cap layer over the second conductive element and the low-k dielectric matrix.

9. The method claimed in claim 1, wherein said inlaying is preceded by forming a stop layer on the low-k dielectric matrix, and
wherein said inlaying is followed by removing the stop layer and forming a cap layer over the second conductive element and the low-k dielectric material.

10. The method claimed in claim 1, wherein producing crosslinking comprises performing thermal processing at a temperature of less than approximately 390 degrees C.

11. The method claimed in claim 1, wherein said decomposing comprises performing thermal processing at a temperature in excess of approximately 390 degrees C.

12. A wiring network of an integrated circuit, comprising:
an integrated circuit substrate comprising a first conductive element;
a second conductive element contacting the first conductive element, the second conductive element having smooth walls;
a layer of porous interlevel dielectric formed over the substrate and surrounding the second conductive element; and
a stop layer formed over the porous interlevel dielectric, the stop layer being permeable to a decomposition product of a porogen of a precursor of the porous interlevel dielectric.

13. The wiring network claimed in claim 12, wherein the second conductive element comprises:
a bulk copper material; and
a continuous layer of barrier material surrounding the bulk copper material.

14. A method for forming a wiring network of an integrated circuit, comprising:
providing an integrated circuit substrate comprising a first conductive element;
applying a first precursor to the substrate, the first precursor comprising a first host thermosetting material and a first porogen;
producing crosslinking of at least some of the first host thermosetting material to form a first low-k dielectric matrix without decomposing all of the first porogen;
forming a first stop layer over the first low-k dielectric matrix;
applying a second precursor to the first stop layer, the second precursor comprising a second host thermosetting material and a second porogen;
producing crosslinking of at least some of the second host thermosetting material to form a second low-k dielectric matrix without decomposing all of the second porogen;
forming a second stop layer over the second low-k dielectric matrix;
forming a trench defining a dual damascene structure in the first and second low-k dielectric matrixes and the first and second stop layers to expose the first conductive element;
inlaying a second conductive element in the trench in contact with the first conductive element; and
decomposing remaining first and second porogen to leave pores in the first and second low-k dielectric matrixes.

15. The method claimed in claim 14, wherein the substrate further comprises a passivation layer overlying at least the first conductive element.

16. The method claimed in claim 14, wherein the first conductive element comprises an interconnect and the second conductive element is a dual damascene structure comprising a via and an interconnect.

17. The method claimed in claim 14, wherein the second conductive element comprises a barrier material surrounding a bulk copper conductor.

18. The method claimed in claim 14, wherein the second stop layer is permeable to decomposition products of the second porogen.

19. The method claimed in claim 14, wherein the first stop layer is permeable to decomposition products of the first porogen, and
wherein the second stop layer is permeable to decomposition products of the first porogen and decomposition products of the second porogen contained in the second precursor.

20. The method claimed in claim 14, wherein producing crosslinking of the second host material is preceded by removing the second stop layer.

21. The method claimed in claim 14, wherein inlaying the second conductive element is followed by selectively depositing a metal cap on the second conductive element.

22. The method claimed in claim 14, wherein inlaying the second conductive element is followed by forming a cap layer over the second conductive element and the second precursor.

23. The method claimed in claim 14, wherein said inlaying is followed by removing the stop layer and forming a cap layer over the second conductive element and the second low-k dielectric matrix.

24. The method claimed in claim 14, wherein the first precursor and the second precursor comprise the same compounds.

25. A wiring network of an integrated circuit, comprising:
an integrated circuit substrate comprising a first conductive element;
a dual damascene conductive element contacting the first conductive element, the dual damascene conductive element having smooth walls; and
first and second layers of porous interlevel dielectric formed over the substrate and surrounding the smooth walls of the dual damascene conductive element, the first and second layers of porous interlevel dielectric being separated by a stop layer.

26. The wiring network claimed in claim 25, wherein the dual damascene conductive element comprises:
a bulk copper material; and
a continuous layer of barrier material surrounding the bulk copper material.
